(19) United States
(12) Patent Application Publication
(10) Pub. No.: US 2025/0294745 A1
(43) Pub. Date: Sep. 18, 2025

(54) SEMICONDUCTOR DEVICE AND MANUFACTURING METHOD THEREOF

(71) Applicant: Kioxia Corporation, Tokyo (JP)

(72) Inventors: Tomotaka ARIGA, Yokkaichi Mie (JP); Saori MATSUSHITA, Yokkaichi Mie (JP)

(73) Assignee: Kioxia Corporation, Tokyo (JP)

(21) Appl. No.: 18/830,247

(22) Filed: Sep. 10, 2024

(30) Foreign Application Priority Data
Mar. 15, 2024 (JP) 2024-041559

(51) Int. Cl. H10B 43/27; H10B 41/27

(52) U.S. Cl. CPC H10B 43/27; H10B 41/27

(57) ABSTRACT

A semiconductor device according to an embodiment includes a plurality of conductive layers, a charge storage film, and an insulation film. The conductive layers are separated from each other in a first direction. The conductive layers each includes a metal film and a first film that covers the metal film and contains titanium silicon nitride. The charge storage film is opposed to side surfaces of the conductive layers. The insulation film is provided between the conductive layers and the charge storage film.

### CROSS-REFERENCE TO RELATED APPLICATIONS

This application is based upon and claims the benefit of priority from the prior Japanese Patent Application No. 2024-41559, filed on Mar. 15, 2024, the entire contents of which are incorporated herein by reference.

### FIELD

The embodiments of the present invention relate to a semiconductor device and a manufacturing method thereof.

### BACKGROUND

In a semiconductor device such as a three-dimensional semiconductor memory, electron escape, that is, escape of electrons captured by a charge storage film to a block dielectric film may occur due to diffusion of hydrogen into the block dielectric film. The electron escape may cause deterioration of the data retention characteristics.

### BRIEF DESCRIPTION OF THE DRAWINGS

FIG. 1 is a block diagram illustrating a schematic configuration of a memory system according to an embodiment;

FIG. 2 is a block diagram illustrating a schematic configuration of a semiconductor storage device according to the embodiment;

FIG. 3 is a circuit diagram illustrating an equivalent circuit of the semiconductor storage device according to the embodiment;

FIG. 4 is a cross-sectional view illustrating a cross-sectional configuration of the semiconductor storage device according to the embodiment;

FIG. 5 is a cross-sectional view illustrating a cross-sectional configuration of a column portion in the semiconductor storage device according to the embodiment;

FIG. 6 is a cross-sectional view illustrating a VI-VI cross-section in FIG. 5 in the semiconductor storage device according to the embodiment;

FIG. 7 is a cross-sectional view illustrating a manufacturing method of the semiconductor storage device according to the embodiment;

FIGS. 8A and 8B are cross-sectional views illustrating a detailed manufacturing method of the semiconductor storage device according to the embodiment;

FIGS. 9A and 9B are cross-sectional views illustrating the manufacturing method of the semiconductor storage device according to the embodiment in continuation from FIG. 8B;

FIGS. 10A and 10B are cross-sectional views illustrating the manufacturing method of the semiconductor storage device according to the embodiment in continuation from FIG. 9B;

FIG. 11 is an explanatory diagram for explaining data retention characteristics of a semiconductor storage device according to a working example;

FIG. 12 is a graph illustrating a relation between a thickness of a barrier metal film and a hydrogen concentration in a second block film in the semiconductor storage device according to the working example;

FIG. 13 is a graph illustrating a relation between a depth of a memory hole in a direction from the periphery to the center and a hydrogen concentration in the semiconductor storage device according to the working example;

FIG. 14 is a graph illustrating a relation between the thickness of the barrier metal film and the data retention characteristics in the semiconductor storage device according to the working example;

FIG. 15 is a graph illustrating a relation between the hydrogen concentration in the second block film and the data retention characteristics in the semiconductor storage device according to the working example;

FIG. 16 is a graph illustrating a relation between the thickness of the barrier metal film and the data retention characteristics in the semiconductor storage device according to the working examples; and

FIG. 17 is a graph illustrating a relation between a SiN/TIN cycle ratio and the data retention characteristics in the semiconductor storage device according to the working examples.

### DETAILED DESCRIPTION

Embodiments will be described below with reference to the drawings. For easier understanding of the descriptions, like constituent elements in the drawings are denoted by like reference signs as much as possible and redundant explanations thereof will be omitted.

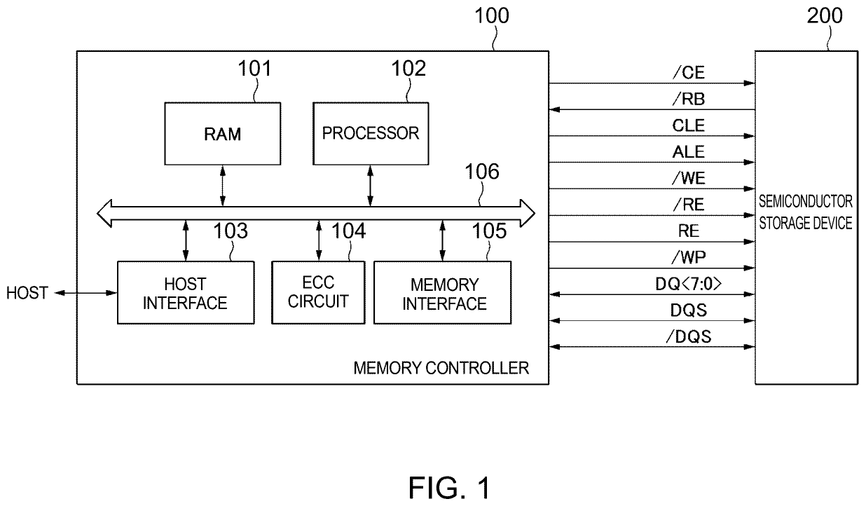

FIG. 1 is a block diagram illustrating a schematic configuration of a memory system according to an embodiment. As illustrated in FIG. 1, the memory system according to the present embodiment includes a memory controller 100 and a semiconductor storage device 200. The semiconductor storage device 200 is an example of a semiconductor device. The semiconductor storage device 200 is a non-volatile semiconductor storage device configured as a NAND flash memory. The memory system can be connected to a host. The host is an electronic device such as a personal computer or a mobile terminal. Although only one semiconductor storage device 200 is illustrated in FIG. 1, an actual memory system includes multiple semiconductor storage devices 200.

The memory controller 100 controls writing of data to the semiconductor storage device 200 in accordance with a write request from the host. The memory controller 100 also controls reading of data from the semiconductor storage device 200 in accordance with a read request from the host. Between the memory controller 100 and the semiconductor storage device 200, signals are transmitted and received which include a chip enable signal/CE, a ready/busy signal/RB, a command latch enable signal CLE, an address latch enable signal ALE, a write enable signal/WE, read enable signals RE and/RE, a write protect signal/WP, a data signal DQ<7:0>, and data strobe signals DQS and/DQS.

The chip enable signal/CE is a signal for enabling the semiconductor storage device 200. The ready/busy signal/RB is a signal for indicating whether the semiconductor storage device 200 is in a ready state or a busy state. The “ready state” is a state where a command from outside can be received. The “busy state” is a state where the command from outside cannot be received. The command latch enable signal CLE is a signal indicating that the signal DQ<7:0> is a command. The address latch enable signal ALE is a signal indicating that the signal DQ<7:0> is an address. The write enable signal/WE is a signal for taking a received signal into the semiconductor storage device 200. The write enable signal/WE is asserted by the memory controller 100 every time a command, an address, and data is received. The memory controller 100 instructs the semiconductor storage device 200 to take in the signal DQ<7:0> while the signal/WE is at a “L (Low)” level.

The read enable signals RE and/RE are signals for the memory controller 100 to read data from the semiconductor storage device 200. The read enable signals RE and/RE are used for controlling an operation timing of the semiconductor storage device 200 when the signal DQ<7:0> is output, for example. The write protect signal/WP is a signal for instructing the semiconductor storage device 200 to prohibit data writing and erasing. The signal DQ<7:0> is data entity transmitted and received between the semiconductor storage device 200 and the memory controller 100 and includes a command, an address, and data. The data strobe signals DQS and/DQS are signals for controlling input and output timings of the signal DQ<7:0>.

The memory controller 100 includes a RAM 101, a processor 102, a host interface 103, an ECC circuit 104, and a memory interface 105. The RAM 101, the processor 102, the host interface 103, the ECC circuit 104, and the memory interface 105 are mutually connected via an internal bus 106.

The host interface 103 outputs a request, user data (write data), and the like received from the host to the internal bus 106. The host interface 103 also transmits user data read from the semiconductor storage device 200, a response from the processor 102, and the like to the host.

The memory interface 105 controls a process of writing user data or the like to the semiconductor storage device 200 and a process of reading user data or the like from the semiconductor storage device 200 based on an instruction from the processor 102. The processor 102 totally controls the memory controller 100. The processor 102 is a CPU or an MPU, for example. When receiving a request from the host via the host interface 103, the processor 102 executes control in accordance with that request. For example, the processor 102 instructs the memory interface 105 to write user data and a parity bit to the semiconductor storage device 200 in accordance with the request from the host. Further, the processor 102 instructs the memory interface 105 to read user data and a parity bit from the semiconductor storage device 200 in accordance with the request from the host.

For user data stored in the RAM 101, the processor 102 determines a storage area (memory area) on the semiconductor storage device 200. The user data is stored in the RAM 101 via the internal bus 106. The processor 102 makes determination of memory area for data in page unit that is the unit of writing (page data). User data stored in one page of the semiconductor storage device 200 is also called “unit data” in the following descriptions. The unit data is typically encoded and stored in the semiconductor storage device 200 as a code word. In the present embodiment, encoding is not essential. Although the memory controller 100 may store the unit data in the semiconductor storage device 200 without encoding, FIG. 1 illustrates a configuration that performs encoding as an example. In a case where the memory controller 100 does not perform encoding, page data is coincident with the unit data. One code word may be created based on one piece of unit data or based on divided data obtained by dividing the unit data. Further, one code word may be created by using a plurality of pieces of unit data.

For every piece of unit data, the processor 102 determines a memory area on the semiconductor storage device 200 to which that piece is written. Physical addresses are assigned to memory areas on the semiconductor storage device 200. The processor 102 manages the memory areas to which unit data is written by using the physical addresses. The processor 102 specifies the determined memory area (physical address) and instructs the memory interface 105 to write the user data to the semiconductor storage device 200. The processor 102 manages the correspondence between a logical address of user data (a logical address managed by the host) and a physical address. When receiving a read request including a logical address from the host, the processor 102 identifies the physical address corresponding to that logical address and instructs the memory interface 105 to read user data by specifying the identified physical address.

The ECC circuit 104 creates a code word by encoding user data stored in the RAM 101. The ECC circuit 104 also decodes a code word read from the semiconductor storage device 200. The RAM 101 temporarily stores therein user data received from the host before the user data is stored in the semiconductor storage device 200, and temporarily stores therein data read from the semiconductor storage device 200 before the read data is transmitted to the host. The RAM 101 is a general-purpose memory such as an SRAM and a DRAM.

FIG. 1 illustrates a configuration example in which the memory controller 100 includes the ECC circuit 104 and the memory interface 105 separately. However, the ECC circuit 104 may be included in the memory interface 105. Further, the ECC circuit 104 may be included in the semiconductor storage device 200. Specific configurations and arrangements of the respective elements illustrated in FIG. 1 are not limited to any particular ones.

When receiving a write request from the host, the memory system in FIG. 1 operates in the following manner. The processor 102 temporarily stores data to be written in the RAM 101. The processor 102 reads the data stored in the RAM 101 and inputs the data to the ECC circuit 104. The ECC circuit 104 encodes the input data and inputs a code word to the memory interface 105. The memory interface 105 writes the input code word to the semiconductor storage device 200.

When receiving a read request from the host, the memory system in FIG. 1 operates in the following manner. The memory interface 105 inputs a code word read from the semiconductor storage device 200 to the ECC circuit 104. The ECC circuit 104 decodes the input code word and stores the decoded data in the RAM 101. The processor 102 transmits the data stored in the RAM 101 to the host via the host interface 103.

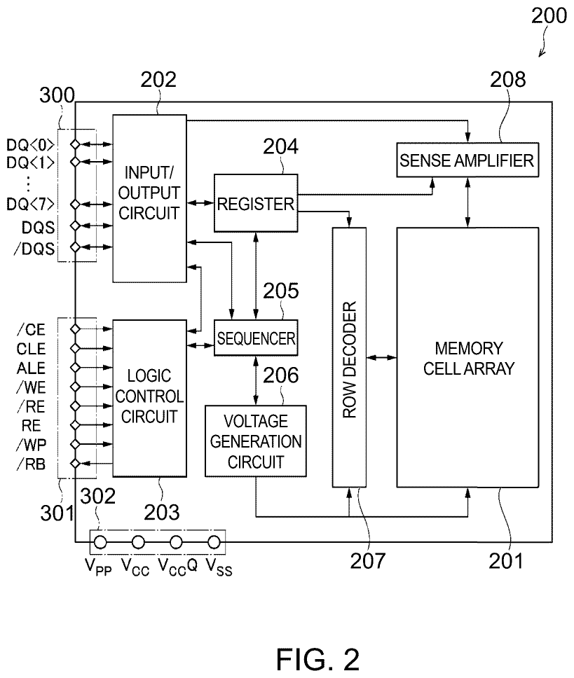

FIG. 2 is a block diagram illustrating a schematic configuration of the semiconductor device according to the embodiment. As illustrated in FIG. 2, the semiconductor storage device 200 includes a memory cell array 201, an input/output circuit 202, a logic control circuit 203, a register 204, a sequencer 205, a voltage generation circuit 206, a row decoder 207, a sense amplifier 208, an input/output pad group 300, a logic control pad group 301, and a power input terminal group 302.

The memory cell array 201 is a part that stores data therein. The memory cell array 201 is configured to include a plurality of memory cell transistors respectively associated with a plurality of bit lines and a plurality of word lines. The input/output circuit 202 transmits and receives the signal DQ<7:0> and the data strobe signals DQS and/DQS to and from the memory controller 100. The input/output circuit 202 also transfers a command and an address in the signal DQ<7:0> to the register 204. Further, the input/output circuit 202 transmits and receives write data and read data to and from the sense amplifier 208.

The logic control circuit 203 receives the chip enable signal/CE, the command latch enable signal CLE, the address latch enable signal ALE, the write enable signal/WE, the read enable signals RE and/RE, and the write protect signal/WP from the memory controller 100. Further, the logic control circuit 203 transfers the ready/busy signal/RB to the memory controller 100 to notify outside of the state of the semiconductor storage device 200.

The register 204 temporarily retains various types of data. For example, the register 204 retains commands instructing a write operation, a read operation, an erase operation, and the like. The command is input to the input/output circuit 202 from the memory controller 100, then transferred to the register 204 from the input/output circuit 202, and retained. The register 204 also retains an address corresponding to the command. This address is input to the input/output circuit 202 from the memory controller 100, then transferred to the register 204 from the input/output circuit 202, and retained. Further, the resister 204 retains status information indicating the operating state of the semiconductor storage device 200. In accordance with the operating state of the memory cell array 201 or the like, the status information is updated by the sequencer 205 each time. The status information is output to the memory controller 100 from the input/output circuit 202 as a state signal in response to a request from the memory controller 100.

The sequencer 205 controls operations of various parts including the memory cell array 201 based on a control signal input from the memory controller 100 to the input/output circuit 202 and the logic control circuit 203. The voltage generation circuit 206 is a part that generates voltages respectively required for a data write operation, a data read operation, and a data erase operation for the memory cell array 201. The voltages include voltages respectively applied to the word lines of the memory cell array 201 and voltages respectively applied to the bit lines thereof, for example. The operation of the voltage generation circuit 206 is controlled by the sequencer 205.

The row decoder 207 is a circuit configured by a group of switches for respectively applying voltages to the word lines of the memory cell array 201. The row decoder 207 receives a block address and a row address from the register 204, selects a block based on the block address, and selects a word line based on the row address. The row decoder 207 switches the opening/closing states of the group of switches so as to allow the voltage from the voltage generation circuit 206 to be applied to the selected word line. The operation of the row decoder 207 is controlled by the sequencer 205.

The sense amplifier 208 is a circuit for adjusting a voltage applied to a bit line of the memory cell array 201 and reading a voltage of a bit line to convert the read voltage to data. In data reading, the sense amplifier 208 acquires data read from a memory cell transistor of the memory cell array 201 to a bit line and transfers the read data thus acquired to the input/output circuit 202. In data writing, the sense amplifier 208 transfers data to be written to a memory cell transistor via a bit line. The operations of the sense amplifier 208 are controlled by the sequencer 205.

The input/output pad group 300 is a part in which a plurality of terminals (pads) for transmitting and receiving various signals between the memory controller 100 and the input/output circuit 202 are provided. The terminals are individually provided to respectively correspond to the various signals that are the signal DQ<7:0> and the data strobe signals DQS and/DQS.

The logic control pad group 301 is a part in which a plurality of terminals for transmitting and receiving various signals between the memory controller 100 and the logic control circuit 203 are provided. The terminals are individually provided to respectively correspond to the various signals that are the chip enable signal/CE, the command latch enable signal CLE, the address latch enable signal ALE, the write enable signal/WE, the read enable signals RE and/RE, the write protect signal/WP, and the ready/busy signal/RB.

The power input terminal group 302 is a part in which a plurality of terminals for receiving application of various voltages required for operations of the semiconductor storage device 200 are provided. The voltages applied to the respective terminals include power-supply voltages Vcc, VccQ, and Vpp, and a ground voltage Vss. The power-supply voltage Vcc is a circuit power-supply voltage supplied from outside as an operating power supply and is about 3.3 V, for example. The power-supply voltage VccQ is 1.2 V, for example. The power-supply voltage VccQ is a voltage used in signal transmission and reception between the memory controller 100 and the semiconductor storage device 200. The power-supply voltage Vpp is higher than the power-supply voltage Vcc and is 12 V, for example.

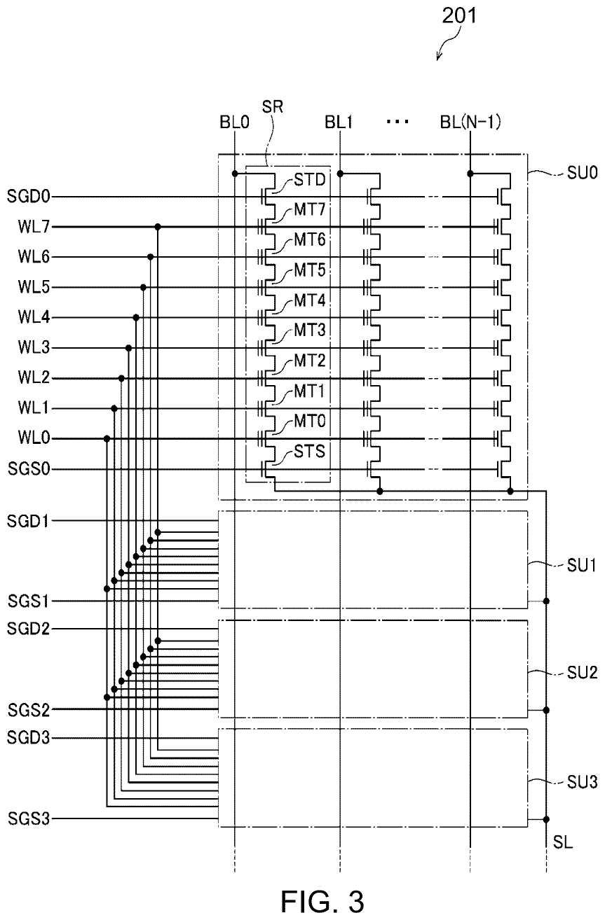

FIG. 3 is a circuit diagram illustrating an equivalent circuit of the semiconductor device according to the embodiment. Next, a configuration of the memory cell array 201 as an electronic circuit is described with reference to FIG. 3. As illustrated in FIG. 3, the memory cell array 201 includes a plurality of string units SU0 to SU3. Each of the string units SU0 to SU3 includes a plurality of NAND strings SR. Each NAND string SR includes eight memory cell transistors MT0 to MT7 and two selection transistors STD and STS, for example. The number of memory cell transistors and the number of selection transistors in each NAND string SR can be changed to any numbers.

The string units SU0 to SU3 form one block as a whole. Although only one block is illustrated in FIG. 3, a plurality of blocks having such a configuration are provided in the memory cell array 201 actually. In the following descriptions, the string units SU0 to SU3 are not distinguished from each other, and each of them is also referred to as a “string unit SU”. Further, the memory cell transistors MT0 to MT7 are not distinguished from each other, and each of them is also referred to as a “memory cell transistor MT”.

The memory cell array 201 includes N bit lines BL0 to BL(N−1), where “N” is a positive integer. Each string unit SU includes the same number of NAND strings SR as N that is the number of the bit lines BL0 to BL(N−1). The memory cell transistors MT0 to MT7 provided in the NAND string SR are arranged in series between the source of the selection transistor STD and the drain of the selection transistor STS. The drain of the selection transistor STD of each NAND string SR is connected to the corresponding one of the bit lines BL0 to BL(N−1). The source of the selection transistor STS is connected to a source line SL. In the following descriptions, the bit lines BL0 to BL(N−1) are not distinguished from each other, and each of them is also referred to as a “bit line BL”.

Each memory cell transistor MT is configured as a transistor including a charge storage film in its gate portion. The amount of charges stored in the charge storage film corresponds to data retained in the memory cell transistor MT.

The memory cell transistor MT in the present embodiment is configured to prevent deterioration of the data retention characteristics caused by electron escape from the charge storage film, as described later. The memory cell transistor MT is a charge-trap type memory cell transistor using a silicon nitride film or the like as a charge storage film, for example. The memory cell transistor MT may be a floating-gate type memory cell transistor using a silicon film or the like as a charge storage film.

The gates of the selection transistors STD provided in the string unit SU0 are all connected to a selection gate line SGD0. To the selection gate line SGD0, a voltage is applied for switching opening/closing of each selection transistor STD. Similarly, the gates of the selection transistors STD in each of the string units SU1 to SU3 are also connected to the corresponding one of selection gate lines SGD1 to SGD3.

The gates of the selection transistors STS provided in the string unit SU0 are all connected to a selection gate line SGS0. To the selection gate line SGS0, a voltage is applied for switching opening/closing of each selection transistor STS. Similarly, the gates of the selection transistors STS in each of the string units SU1 to SU3 are also connected to the corresponding one of selection gate lines SGS1 to SGS3. The string units SU0 to SU3 forming one block may share the selection gate line, and the gates of the selection transistors STS in the respective string units SU0 to SU3 may be connected to the common selection gate line.

The gates of the memory cell transistors MT0 to MT7 are connected to the word lines WL0 to WL7, respectively. To each of the word lines WL0 to WL7, a voltage is applied for the purpose of switching opening/closing of the corresponding one of the memory cell transistors MT0 to MT7, changing the amount of charges stored in the charge storage film of the corresponding one of the memory cell transistors MT0 to MT7, or the like.

Data writing and data reading for the semiconductor storage device 200 are performed for the memory cell transistors MT connected to any of the word lines WL in any of the string units SU all at once for each unit called a “page”. On the other hand, data erasing for the semiconductor storage device 200 is performed for all the memory cell transistors MT included in a block all at once. Various known methods can be adopted as specific methods for performing the data writing, reading, and erasing described above, and therefore detailed descriptions thereof are omitted.

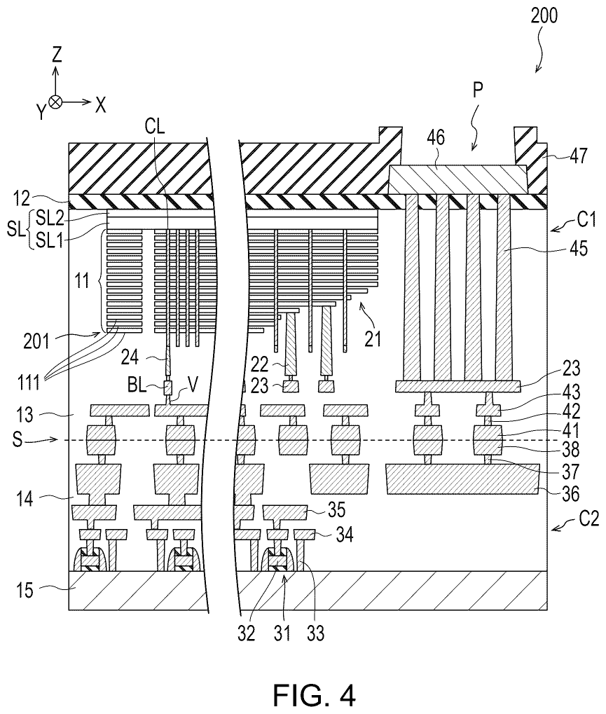

FIG. 4 is a cross-sectional view illustrating a cross-sectional configuration of the semiconductor storage device 200 according to the embodiment. Next, a configuration of the semiconductor storage device 200, in particular, a configuration of the memory cell array 201 and its surroundings is specifically described with reference to FIG. 4. As illustrated in FIG. 4, the semiconductor storage device 200 is a three-dimensional memory in which an array chip C1 having the memory cell array 201 and a circuit chip C2 having a peripheral circuit are bonded to each other. The peripheral circuit includes the sense amplifier 208 and the row decoder 207 illustrated in FIG. 2, for example. The array chip C1 and the circuit chip C2 are bonded to each other at a bonding surface S. That is, the array chip C1 and the circuit chip C2 are electrically connected to each other at the bonding surface S via joined wires. Therefore, the semiconductor storage device 200 according to the present embodiment has a CBA (CMOS directly Bonded to Array) configuration.

The circuit chip C2 includes a substrate 15, a plurality of transistors 31, a plurality of contact plugs 33, wiring layers 34, 35, and 36, a plurality of via plugs 37, a plurality of metal pads 38, and an interlayer dielectric film 14. In the following description, directions parallel to the surface, that is, the top surface of the substrate 15 and perpendicular to each other are defined as an X direction and a Y direction. Further, a direction perpendicular to the surface of the substrate 15 is defined as a Z direction. The Z direction is an example of a first direction. In the following descriptions, the plus side of the Z direction may be referred to as an “upward direction”, and the minus side of the Z direction may be referred to as a “downward direction”.

The substrate 15 is a semiconductor substrate such as a silicon substrate. The transistors 31 configure a CMOS circuit. Each transistor 31 includes a gate electrode 32 provided on the substrate 15 via a gate dielectric film and a source diffusion layer and a drain diffusion layer (both not illustrated) that are provided in the substrate 15. A semiconductor element other than the transistors 31, such as a resistor element and a capacitor element, may be formed on the substrate 15.

The contact plug 33 is provided on the source diffusion layer or the drain diffusion layer of the corresponding transistor 31.

The wiring layer 34 is provided on the contact plugs 33. The wiring layer 34 includes a plurality of wires each connected to the corresponding contact plug 33. The wiring layer 35 is provided on the wiring layer 34. The wiring layer 35 includes a plurality of wires each connected to the corresponding wire in the wiring layer 34. The wiring layer 36 is provided on the wiring layer 35. The wiring layer 36 includes a plurality of wires each connected to the corresponding wire in the wiring layer 35.

The via plugs 37 are each provided on the corresponding wire in the wiring layer 36. The metal pads 38 are each provided on the corresponding via plug 37. The wiring layers 34 to 36, the via plugs 37, and the metal pads 38 may be made of a low-resistance metal such as copper and tungsten. The interlayer dielectric film 14 covers and protects the transistors 31, the contact plugs 33, the wiring layers 34 to 36, the via plugs 37, and the metal pads 38. The interlayer dielectric film 14 is a silicon oxide (SiOₓ) film, for example.

The array chip C1 includes a stacked film 11, a column portion CL, the source line SL, an interlayer dielectric film 13, and an insulation film 12.

The stacked film 11 is provided above the transistor 31 of the circuit chip C2. That is, the stacked film 11 is arranged in the Z direction with respect to the substrate 15. The stacked film 11 is configured by a plurality of conductive layers 111 and a plurality of insulation layers (not illustrated) alternately stacked in the Z direction. One or a plurality of the conductive layers 111 at upper and lower ends in the Z direction of the stacked film 11 serve as the source-side selection gate line SGS and the drain-side selection gate line SGD, for example. The source-side selection gate line SGS is provided in an upper region of the stacked film 11, for example. The drain-side selection gate line SGD is provided in a lower region of the stacked film 11, for example. The conductive layers 111 arranged between the source-side selection gate line SGS and the drain-side selection gate line SGD serve as the word lines WL. The bit lines BL are arranged below the stacked film 11. The bit lines BL are formed to extend in the Y direction.

A stair structure portion 21 is provided at an end of the stacked film 11 in the X direction. A portion of the stacked film 11 which serves as the word line WL is electrically connected to a wiring layer 23 via a contact 22. The source line SL is provided above the stacked film 11 via an insulation film. The source line SL includes a lower layer SL1 and an upper layer SL2. The lower layer SL1 is made of a semiconductor material such as silicon. The upper layer SL2 is made of a metal material such as tungsten.

The column portion CL is provided in the stacked film 11 to penetrate therethrough in the Z direction. The lower end of the column portion CL is electrically connected to the bit line BL via a via plug 24. The bit line BL is included in the wiring layer 23. The upper end of the column portion CL is electrically connected to the source line SL. A wiring layer 43 including a via plug V is provided below the wiring layer 23. Via plugs 42 are provided below the wiring layer 43. A plurality of metal pads 41 are provided below the via plugs 42. The via plug 24, the wiring layers 23, 42, and 43, and the metal pads 41 are made of a low-resistance metal such as copper and tungsten.

The insulation film 12 is provided above the stacked film 11. The insulation film 12 is a silicon oxide film or a silicon nitride (SIN) film, for example. A via plug 45 is provided in a portion of the array chip C1 shifted from the stacked film 11 in the X direction. The via plug 45 is formed to extend upward from the wiring layer 23. A metal pad 46 is provided on the top surface of the insulation film 12. The upper end of the via plug 45 penetrates through the insulation film 12 and is electrically connected to the metal pad 46. The metal pad 46 is a metal film containing copper, for example. The metal pad 46 serves as an external connection pad of the semiconductor storage device 200. On the top surface of the insulation film 12, a passivation film 47 is further provided so as to allow the metal pad 46 to be exposed. The passivation film 47 is a silicon oxide film, for example. The passivation film 47 has an opening P through which the top surface of the metal pad 46 is exposed. The metal pad 46 can be connected to a mounting board or another device by a bonding wire or the like through the opening P.

The interlayer dielectric film 13 of the array chip C1 and the interlayer dielectric film 14 of the circuit chip C2 are bonded to each other at the bonding surface S. Further, the metal pad 41 of the array chip C1 and the metal pad 38 of the circuit chip C2 are joined to each other at the bonding surface S. Accordingly, the array chip C1 and the circuit chip C2 are electrically connected to each other via the metal pads 38 and 41.

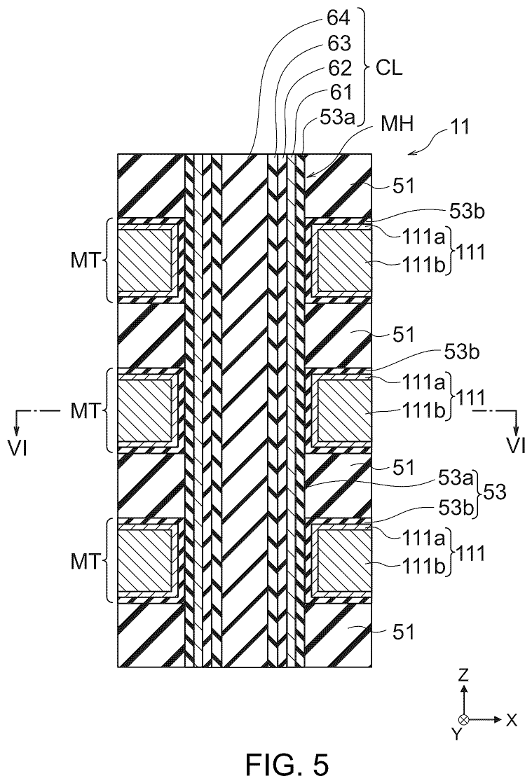

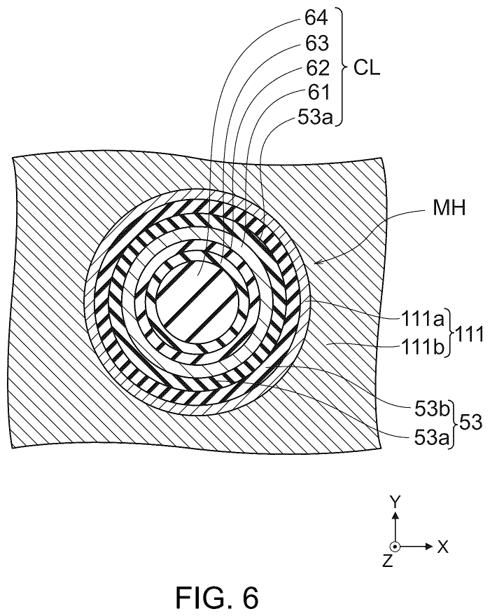

FIG. 5 is a cross-sectional view illustrating a cross-sectional configuration of the column portion CL in the semiconductor storage device 200 according to the embodiment. That is, FIG. 5 is a cross-sectional view illustrating a cross-sectional configuration of the stacked film 11 when the column portion CL is cut along a plane (X-Z plane) passing through the center axis of the column portion CL. FIG. 6 is a cross-sectional view illustrating a VI-VI cross-section in FIG. 5 in the semiconductor device according to the embodiment. Next, a configuration of the stacked film 11 is described with reference to FIGS. 5 and 6.

As illustrated in FIG. 5, the stacked film 11 has a configuration in which the conductive layers 111 and a plurality of insulation layers 51 are alternately stacked in the Z direction. The conductive layer 111 is a layer with conductivity. The conductive layer 111 includes a metal film 111b, a barrier metal film 111a, and a first block film 53b. The first block film 53b is a portion of a block dielectric film 53. The barrier metal film 111a is an example of a first film. The block dielectric film 53 is an example of an insulation film. The first block film 53b is an example of a first insulation film.

The stacked film 11 has a plurality of memory holes MH formed therein and extending in the Z direction. The memory hole MH is an example of a first concave portion. The column portion CL illustrated in FIG. 4 is provided in each memory hole MH. Each column portion CL corresponds to the NAND string SR illustrated in FIG. 3.

As illustrated in FIG. 6, the column portion CL has a circular or elliptical cross-sectional shape. The column portion CL includes a second block film 53a, a charge storage film 61, a tunnel dielectric film 62, a channel semiconductor film 63, and a core dielectric film 64 in that order from outside of the memory hole MH to inside. The second block film 53a is another portion of the block dielectric film 53. The second block film 53a is an example of a second insulation film. The tunnel dielectric film 62 is an example of a third insulation film. The channel semiconductor film 63 is an example of a semiconductor film. The core dielectric film 64 is an example of a fourth insulation film. The second block film 53a, the charge storage film 61, and the tunnel dielectric film 62 are also referred to as a “memory film” collectively. The channel semiconductor film 63 and the core dielectric film 64 are also referred to as a “body” collectively.

The metal film 111b of the conductive layer 111 contains molybdenum (Mo) as the main component, for example. The metal film 111b may contain a transition element other than molybdenum, such as tungsten (W), titanium (Ti), and niobium (Nb).

The barrier metal film 111a of the conductive layer 111 covers the metal film 111b. The barrier metal film 111a improves adhesion between the conductive layer 111 and the first block film 53b. To prevent deterioration of the data retention characteristics, the barrier metal film 111a contains titanium silicon nitride (TiSiN) as the main component. The silicon concentration in the barrier metal film 111a may be 54% or more. The thickness of the barrier metal film 111a may be 3 nm or less.

Each conductive layer 111 is used as any of the word lines WL0 to WL7 or the selection gate line SGS or SGD in FIG. 3, for example.

The insulation layer 51 is arranged between the conductive layers 111 and 111 adjacent to each other in the Z direction. The insulation layer 51 electrically insulates those adjacent conductive layers 111 and 111 from each other. The insulation layer 51 is made of silicon oxide (SiO₂), for example.

The first block film 53b of the block dielectric film 53 is provided to be in contact with the barrier metal film 111a. The first block film 53b prevents back tunneling of charges from the conductive layer 111 toward the memory films 53a, 61, and 62. The first block film 53b contains aluminum oxide (Al₂O₃) as the main component, for example.

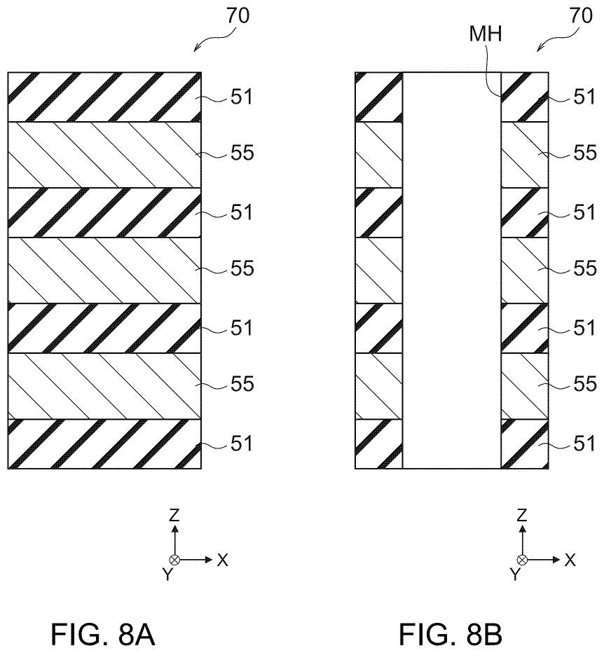

The second block film 53a is provided between the first block film 53b and the charge storage film 61. That is, the block dielectric film 53 is provided between the conductive layer 111 and the charge storage film 61. The second block film 53a prevents back tunneling of charges from the conductive layer 111 toward the memory films 61 and 62. Further, the second block film 53a protects the charge storage film 61 from being etched in a replacing process that replaces sacrifice layers 55 (see FIGS. 8) with the conductive layers 111 when the semiconductor storage device 200 is manufactured. The second block film 53a is also referred to as a “cover dielectric film”. The second block film 53a contains silicon oxide (SiO₂) as the main component, for example.

In the present embodiment, the barrier metal film 111a contains titanium silicon nitride (TiSiN) having the barrier properties against hydrogen. Since the barrier metal film 111a contains titanium silicon nitride, the concentration of hydrogen contained in the memory cell array 201 is made at a suitable concentration to prevent electron escape in the charge storage film 61. Hydrogen is an example of an impurity.

Specifically, the hydrogen concentration at the interface between the barrier metal film 111a and the first block film 53b is higher, and the hydrogen concentration in the second block film 53a is lower. The hydrogen concentration is an example of an impurity concentration.

The hydrogen concentration in the first block film 53b may be higher, and the hydrogen concentration in the second block film 53a may be lower.

The hydrogen concentration at the interface between the barrier metal film 111a and the first block film 53b may be higher than 1×10²⁰ atoms/cm³. Further, the second block film 53a may include a first portion that is lower in hydrogen concentration than the interface between the barrier metal film 111a and the first block film 53b and a second portion located on the charge storage film 61 side of the first portion. The second portion is a portion being larger in thickness (i.e., thickness in the radial direction of the memory hole MH) than the first portion and having a hydrogen concentration of 1×10²⁰ atoms/cm³ or less which is lower than that of the first portion. That is, the second block film 53a may be lower in hydrogen concentration than the interface between the barrier metal film 111a and the block dielectric film 53 and may partially have a hydrogen concentration of 1×10²⁰ atoms/cm³ or less.

Further, the hydrogen concentration in the barrier metal film 111a may increase from the metal film 111b side to the block dielectric film 53 side. The hydrogen concentration in the block dielectric film 53 may decrease from the barrier metal film 111a side to the charge storage film 61 side.

The hydrogen concentration in the barrier metal film 111a may increase from the metal film 111b side to the block dielectric film 53 side substantially monotonically. The hydrogen concentration in the block dielectric film 53 may decrease from the barrier metal film 111a side to the charge storage film 61 side substantially monotonically.

Around the interface between the barrier metal film 111a and the first block film 53b, the hydrogen concentration may have a local maximum value at which an increasing trend changes to a decreasing trend.

The hydrogen concentration in a portion of the barrier metal film 111a on the block dielectric film 53 side may be 1×10²⁰ atoms/cm³ or more. In this case, this portion of the barrier metal film 111a may be a portion on one side of an intermediate position between one end of the barrier metal film 111a on the metal film 111b side and another end of the barrier metal film 111a on the block dielectric film 53 side, the one side being closer to the other end than to the one end.

Further, in the second block film 53a, the amount of decrease in hydrogen concentration in a direction from the barrier metal film 111a to the charge storage film 61 may be larger than the amount of decrease in hydrogen concentration in the first block film 53b.

The charge storage film 61 is opposed to side surfaces of the conductive layers 111. The charge storage film 61 is a silicon nitride film, for example. The charge storage film 61 has trap sites that trap charges in the film. A portion of the charge storage film 61 which is sandwiched between the conductive layer 111 and the channel semiconductor film 63 configures an area for storing charges therein, that is, a storage area of the memory cell transistor MT. A threshold voltage of the memory cell transistor MT is varied depending on whether charges are present in the charge storage film 61 or in accordance with the amount of those charges. The memory cell transistor MT of the present embodiment is the MONOS (Metal-Oxide-Nitride-Oxide-Silicon) type using an insulation film as the charge storage film 61.

The tunnel dielectric film 62 is provided on the side surface of the charge storage film 61 on the opposite side to the block dielectric film 53. The tunnel dielectric film 62 contains silicon oxide, or silicon oxide and silicon nitride, for example. The tunnel dielectric film 62 serves as a potential barrier between the channel semiconductor film 63 and the charge storage film 61. For example, when electrons are injected from the channel semiconductor film 63 to the charge storage film 61 (i.e., in a write operation), the electrons pass (i.e., tunnel) through the potential barrier formed by the tunnel dielectric film 62. When holes are injected from the channel semiconductor film 63 to the charge storage film 61 (i.e., in an erase operation), the holes pass through the potential barrier formed by the tunnel dielectric film 62.

The channel semiconductor film 63 is provided on the side surface of the tunnel dielectric film 62 on the opposite side to the charge storage film 61. The channel semiconductor film 63 is made of polysilicon (Poly-Si), for example. The channel semiconductor film 63 forms the channel of the memory cell transistor MT or the like.

The core dielectric film 64 is provided on the side surface of the channel semiconductor film 63 on the opposite side to the tunnel dielectric film 62. The core dielectric film 64 is made of silicon oxide, for example.

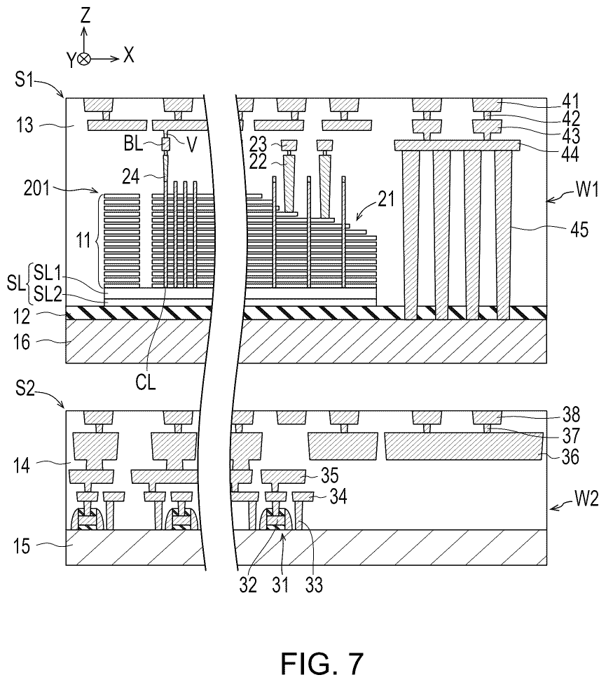

Next, a manufacturing method of the semiconductor storage device 200 is described. FIG. 7 is a cross-sectional view illustrating a manufacturing method of the semiconductor storage device 200 according to the embodiment. First, as illustrated in FIG. 7, the memory cell array 201, the insulation film 12, the interlayer dielectric film 13, the stair structure portion 21, the metal pad 41, and the like are formed on the substrate 16 of a memory wafer W1. In this process, the via plug 45, the wiring layer 44, the wiring layer 43, the via plug 42, and the metal pad 41 are formed on the substrate 16 in turn. Further, the interlayer dielectric film 14, the transistor 31, the metal pad 38, and the like are formed on the substrate 15 of a circuit wafer W2. In this process, the contact plug 33, the wiring layer 34, the wiring layer 35, the wiring layer 36, the via plug 37, and the metal pad 38 are formed on the substrate 15 in turn. Next, the array wafer W1 and the circuit wafer W2 are bonded to each other by mechanical pressure. The interlayer dielectric film 13 and the interlayer dielectric film 14 thus adhere to each other. Next, the array wafer W1 and the circuit wafer W2 are annealed at 400° C., for example. Accordingly, the metal pad 41 and the metal pad 38 are joined to each other.

Thereafter, the substrate 15 is made thinner by CMP, the substrate 16 is removed by CMP, and then the array wafer W1 and the circuit wafer W2 are cut into a plurality of chips. The semiconductor storage device 200 in FIG. 4 is thus manufactured. The metal pad 46 and the passivation film 47 are formed on the insulation film 12, for example, after the substrate 15 is made thinner and the substrate 16 is removed.

FIGS. 8A and 8B are cross-sectional views illustrating a detailed manufacturing method of the semiconductor storage device 200 according to the embodiment. In more detail, as illustrated in FIG. 8A, a stacked film 70 is formed by alternately stacking the insulation layers 51 and the sacrifice layers 55 above the substrate 16 (see FIG. 7). The sacrifice layer 55 is an example of a first layer. The insulation layer 51 is a SiO₂ film, for example. The insulation layer 51 is formed by plasma CVD (Chemical Vapor Deposition) using SiH₄ gas and N₂O gas, for example. The sacrifice layer 55 is a layer to be replaced with the conductive layer 111. The sacrifice layer 55 is a SiN film, for example. The sacrifice layer 55 is formed by plasma CVD using SiH₂Cl₂ gas and NH₃ gas, for example. After the stacked film 70 is formed, as illustrated in FIG. 8B, the memory hole MH is formed to penetrate through the stacked film 70. The memory hole MH is formed by lithography and RIE (Reactive Ion Etching), for example.

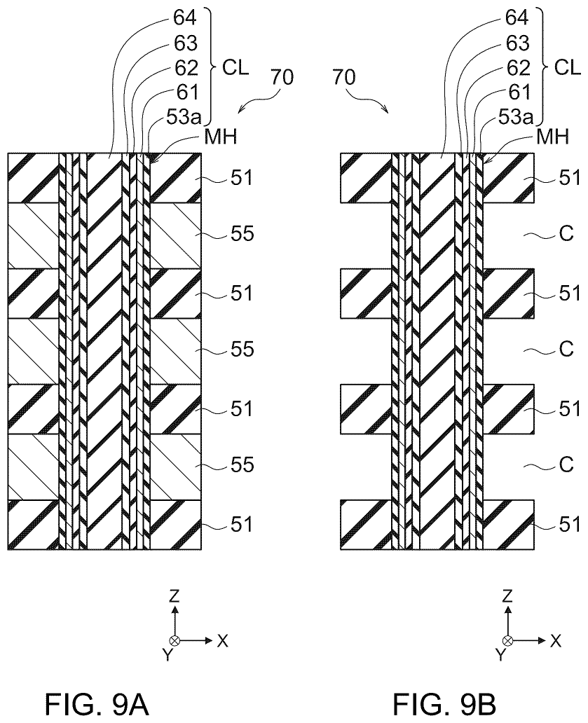

FIGS. 9A and 9B are cross-sectional views illustrating the manufacturing method of the semiconductor storage device 200 according to the embodiment in continuation from FIG. 8B. After the memory hole MH is formed, as illustrated in FIG. 9A, the column portion CL is embedded in the memory hole MH.

That is, the second block film 53a is formed on the side surfaces of the conductive layers 51 and the sacrifice layers 55. The second block film 53a is a SiO₂ film, for example. The second block film 53a is formed by ALD (Atomic Layer Deposition) using TDMAS (tris(dimethylamino)silane) gas, for example. The second block film 53a may be formed on the side surfaces of the sacrifice layers 55 by directly oxidizing the side surfaces of the sacrifice layers 55 by radical oxidation.

After the second block film 53a is formed, the charge storage film 61 is formed on the side surface of the second block film 53a on the opposite side to the conductive layers 51 and the sacrifice layers 55. The charge storage film 61 is a SiN film, for example. The charge storage film 61 is formed by ALD using SiH₂Cl₂ gas and NH₃ gas under a reduced-pressure environment (at 2000 Pa or less) at a temperature of 300° C. or more and 800° C. or less, for example.

After the charge storage film 61 is formed, the tunnel dielectric film 62 is formed on the side surface of the charge storage film 61 on the opposite side to the second block film 53a. The tunnel dielectric film 62 is a SiON film, for example. The tunnel dielectric film 62 is formed by ALD using HCD (hexachlorodisilane) gas, NH₃ gas, and O₂ gas under a reduced-pressure environment (at 2000 Pa or less) at a temperature of 400° C. or more and 800° C. or less, for example.

After the tunnel dielectric film 62 is formed, the channel semiconductor film 63 is formed on the side surface of the tunnel dielectric film 62 on the opposite side to the charge storage film 61. The channel semiconductor film 63 is a Si film, for example. The channel semiconductor film 63 is formed by CVD using SiH₄ gas under a reduced-pressure environment (at 2000 Pa or less) at a temperature of 400° C. or more and 800° C. or less, for example, and is then annealed to be crystallized. The Si film is thus changed from amorphous silicon to polysilicon.

After the channel semiconductor film 63 is formed, the core dielectric film 64 is formed on the side surface of the channel semiconductor film 63 on the opposite side to the tunnel dielectric film 62. The core dielectric film 64 is a SiO₂ film, for example. The core dielectric film 64 is formed by CVD using TEOS (tetraethyl orthosilicate), for example.

After the column portion CL is embedded in the memory hole MH as described above, a groove (not illustrated) is formed in the stacked film 70. After the groove is formed, the sacrifice layers 55 are removed by wet etching using the formed groove. A chemical solution such as hot phosphoric acid is used in the wet etching. As illustrated in FIG. 9B, by removing the sacrifice layers 55, cavities C are formed between the insulation layers 51 and 51 adjacent to each other. The cavity C is an example of a second concave portion. In the cavity C, the surfaces in the Z direction of the insulation layers 51 and the side surface of the second block film 53a are exposed.

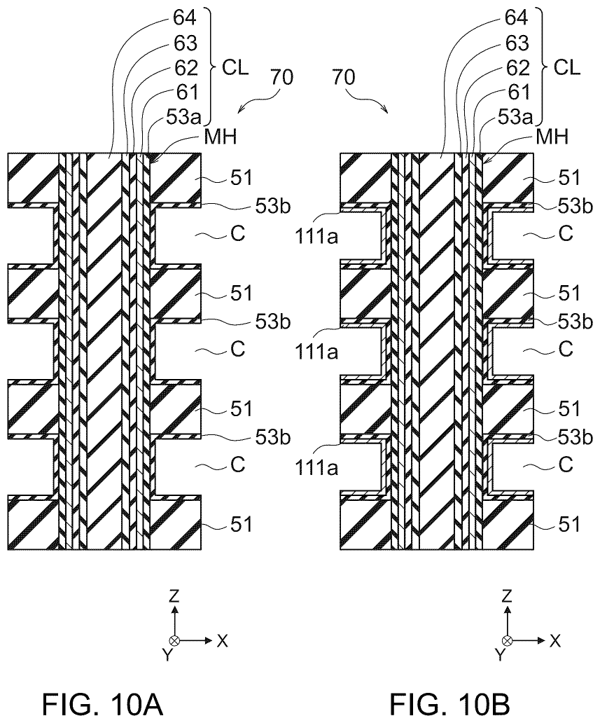

FIGS. 10A and 10B are cross-sectional views illustrating the manufacturing method of the semiconductor storage device 200 according to the embodiment in continuation from FIG. 9B. After the cavities C are formed, as illustrated in FIG. 10A, the first block film 53b is formed on the surfaces in the Z direction of the insulation layers 51 and the side surface of the second block film 53a. The first block film 53b is an Al₂O₃ film, for example. The first block film 53b is formed by ALD using AlCl₃ gas and O₃ gas under a reduced-pressure environment (at 2000 Pa or less) at a temperature of 200° C. or more and 500° C. or less, for example.

After the first block film 53b is formed, as illustrated in FIG. 10B, the barrier metal film 111a is formed in the cavity C in which the first block film 53b has been formed. The barrier metal film 111a is a TiSiN film, for example. The barrier metal film 111a is formed by repeating cycle deposition of TiN film and cycle deposition of SiN film by CVD or ALD, for example. The TIN film is formed by using TiCl₄ gas and NH₃ gas. The SiN film is formed by using SiH₂Cl₂ gas and NH₃ gas. After the barrier metal film 111a is formed, the metal film 111b (see FIG. 5) is formed in the cavity C in which the barrier metal film 111a has been formed. The metal film 111b is a Mo film, for example. The metal film 111b is formed by ALD using MoO₂Cl₂ gas and H₂ gas under an environment of a temperature of 600° C., for example.

### Specific Working Examples

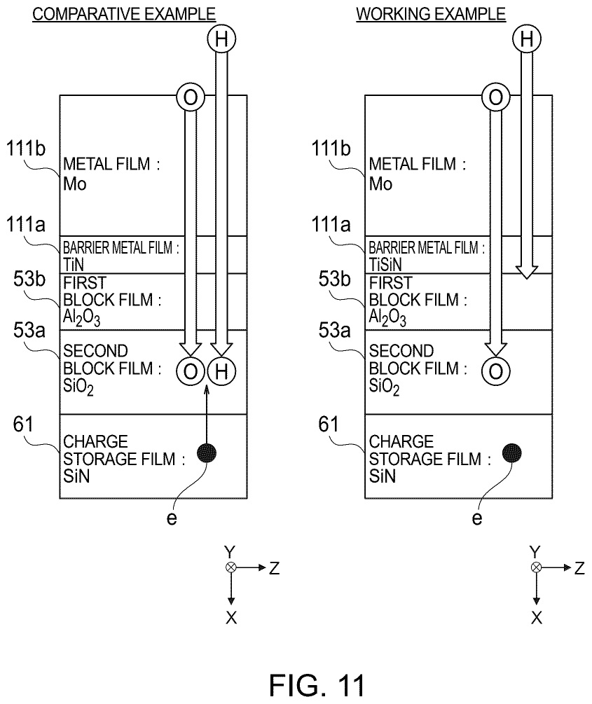

Next, specific working examples of the above-described embodiment are described. In the working examples described below, data retention characteristics of the semiconductor storage device 200 are described while being compared with those in a comparative example. FIG. 11 is an explanatory diagram for explaining the data retention characteristics of the semiconductor storage device 200 according to a working example.

As illustrated in FIG. 11, a semiconductor storage device according to a comparative example includes the metal film 111b formed by a Mo film, the barrier metal film 111a formed by a TiN film, the first block film 53b formed by an Al₂O₃ film, the second block film 53a formed by a SiO₂ film, and the charge storage film 61 formed by a SiN film in that order toward the plus side of the X direction. The configuration inside the charge storage film 61 in the memory hole MH is omitted. In the semiconductor storage device according to the comparative example, the barrier metal film 111a is formed by a TiN film. Therefore, it is difficult for the barrier metal film 111a to prevent diffusion of hydrogen from the metal film 111b side to the block dielectric film 53 side. In FIG. 11, the symbol “H” represents hydrogen, the symbol “O” represents oxygen, the symbol “OH” represents OH radicals (i.e., hydroxyl radicals), and the symbol “e” represents electrons. Since it is difficult for the barrier metal film 111a to prevent diffusion of hydrogen, hydrogen and oxygen are bonded to each other to generate OH radicals in the second block film 53a. The OH radicals tend to steal electrons stored in the charge storage film 61 because of the strong oxidizing power thereof. Consequently, electron escape in which electrons move toward the second block film 53a occurs in the charge storage film 61. The electron escape causes deterioration of the data retention characteristics.

Meanwhile, as illustrated in FIG. 11, the semiconductor storage device 200 according to the working example is different from the semiconductor storage device according to the comparative example in that the barrier metal film 111a is formed by a TiSiN film. The barrier metal film 111a according to the working example can prevent diffusion of hydrogen from the metal film 111b side to the block dielectric film 53 side because the barrier metal film 111a is formed by a TiSiN film. Since the barrier metal film 111a can prevent diffusion of hydrogen, it is possible to prevent bonding of hydrogen and oxygen and generation of OH radicals in the second block film 53a. Accordingly, occurrence of electron escape can be prevented in the charge storage film 61. By preventing the occurrence of electron escape, deterioration of the data retention characteristics can be prevented.

Next, descriptions are provided for characteristics related to the hydrogen concentration measured from each of the semiconductor storage device of the comparative example and the semiconductor storage device 200 of the working example. The characteristics described below can be obtained by composition analysis, for example, SIMS (Secondary Ion Mass Spectrometry).

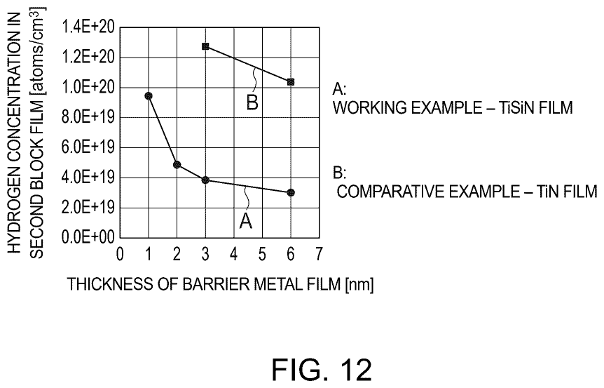

FIG. 12 is a graph illustrating a relation between a thickness of the barrier metal film 111a and a hydrogen concentration in the second block film 53a in the semiconductor storage device 200 according to the working example. In FIG. 12, the horizontal axis represents the thickness (nm) of the barrier metal film 111a. The vertical axis represents the hydrogen concentration (atoms/cm³) in the second block film 53a. Reference sign A in FIG. 12 represents the hydrogen concentration in the second block film 53a in the semiconductor storage device 200 according to the working example. That is, the reference sign A represents the hydrogen concentration in the second block film 53a in a case where the barrier metal film 111a is formed by a TiSiN film. Reference sign B in FIG. 12 represents the hydrogen concentration in the second block film 53a in the semiconductor storage device according to the comparative example. That is, the reference sign B represents the hydrogen concentration in the second block film 53a in a case where the barrier metal film 111a is formed by a TiN film.

As illustrated in FIG. 12, the hydrogen concentration in the second block film 53a is varied with the thickness of the barrier metal film 111a. As is apparent from FIG. 12, at the same thickness of the second block film 53a, the hydrogen concentration in the second block film 53a is lower in a case where the barrier metal film 111a is formed by a TiSiN film than in a case where the barrier metal film 111a is formed by a TiN film. This fact shows that the semiconductor storage device 200 according to the working example is superior to the semiconductor storage device according to the comparative example in prevention of diffusion of hydrogen from the metal film 111b side to the block dielectric film 53 side.

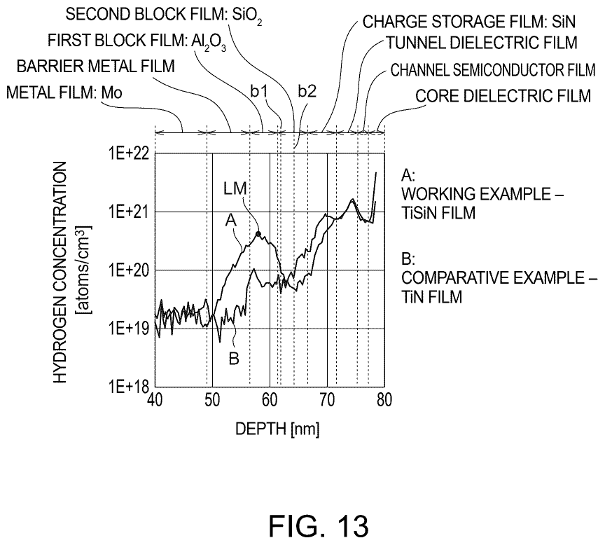

FIG. 13 is a graph illustrating a relation between a depth of the memory hole MH in a direction from the periphery to the center and a hydrogen concentration in the semiconductor storage device 200 according to the working example. In FIG. 13, the horizontal axis represents the depth (nm). The vertical axis represents the hydrogen concentration (atoms/cm³). In FIG. 13, the components corresponding to the range of depth are illustrated to correspond to the horizontal axis. In FIG. 13, the position at a depth of 0 (nm) is set on the metal film 111b. The hydrogen concentrations corresponding to the depth range from 0 (nm) to 40 (nm) are not illustrated. Reference sign A in FIG. 13 represents the hydrogen concentration in the semiconductor storage device 200 according to the working example in which the barrier metal film 111a is formed by a TiSiN film. Reference sign B in FIG. 13 represents the hydrogen concentration in the semiconductor storage device according to the comparative example in which the barrier metal film 111a is formed by a TiN film.

In the example illustrated in FIG. 13, the semiconductor storage device according to the comparative example has a lower hydrogen concentration at the interface between the barrier metal film 111a and the first block film 53b and a higher hydrogen concentration in the second block film 53a. Meanwhile, the semiconductor storage device 200 according to the working example has a higher hydrogen concentration at the interface between the barrier metal film 111a and the first block film 53b and a lower hydrogen concentration in the second block film 53a. Therefore, the magnitude relation between the hydrogen concentration at the interface between the barrier metal film 111a and the first block film 53b and the hydrogen concentration in the second block film 53a is reversed between the semiconductor storage device according to the comparative example and the semiconductor storage device 200 according to the working example. The high hydrogen concentration at the interface between the barrier metal film 111a and the first block film 53b means that diffusion of hydrogen from the metal film 111b side to the block dielectric film 53 side is prevented at this interface.

Further, in the example illustrated in FIG. 13, the semiconductor storage device according to the comparative example has a lower hydrogen concentration in the first block film 53b and a higher hydrogen concentration in the second block film 53a. Meanwhile, the semiconductor storage device 200 according to the working example has a higher hydrogen concentration in the first block film 53b and a lower hydrogen concentration in the second block film 53a. Therefore, the magnitude relation between the hydrogen concentration in the first block film 53b and the hydrogen concentration in the second block film 53a is reversed between the semiconductor storage device according to the comparative example and the semiconductor storage device 200 according to the working example.

Furthermore, in the example illustrated in FIG. 13, in the semiconductor storage device according to the comparative example, the hydrogen concentration at the interface between the barrier metal film 111a and the first block film 53b is lower than 1×10²⁰ (i.e., 1E+20) atoms/cm³. On the other hand, in the semiconductor storage device 200 according to the working example, the hydrogen concentration at the interface between the barrier metal film 111a and the first block film 53b is higher than 1×10²⁰ atoms/cm³. Therefore, the magnitude relation between the hydrogen concentration at the interface between the barrier metal film 111a and the first block film 53b and 1×10²⁰ atoms/cm³ is reversed between the semiconductor storage device according to the comparative example and the semiconductor storage device 200 according to the working example.

In addition, in the example illustrated in FIG. 13, the second block film 53a of the semiconductor storage device according to the comparative example has a first portion with a hydrogen concentration of 1×10²⁰ atoms/cm³ or more and a second portion with a hydrogen concentration of 1×10²⁰ atoms/cm³ or less. The first portion is located on the charge storage film 61 side of the second portion. The broken line b2 in FIG. 13 represents the boundary between the first portion and the second portion in the second block film 53a in the comparative example. In the second block film 53a in the comparative example, the thickness of the second portion is about the same as the thickness of the first portion. On the other hand, the second block film 53a of the semiconductor storage device 200 according to the working example also has the first portion with a hydrogen concentration of 1×10²⁰ atoms/cm³ or more and the second portion with a hydrogen concentration of 1×10²⁰ atoms/cm³ or less. However, in the second block film 53a in the working example, the second portion is located on the charge storage film 61 side of the first portion. The broken line b1 in FIG. 13 represents the boundary between the first portion and the second portion in the second block film 53a of the working example. Further, in the second block film 53a of the working example, the first portion is lower in hydrogen concentration than the interface between the barrier metal film 111a and the first block film 53b. Furthermore, in the second block film 53a in the working example, the second portion is larger in thickness than the first portion. That is, the second block film 53a in the working example is lower in hydrogen concentration than the interface between the barrier metal film 111a and the block dielectric film 53 and partially has a hydrogen concentration of 1×10²⁰ atoms/cm³ or less. Therefore, the arrangement of the portion with a hydrogen concentration of 1×10²⁰ atoms/cm³ or less in the second block film 53a is different between the semiconductor storage device according to the comparative example and the semiconductor storage device 200 according to the working example.

In addition, in the example illustrated in FIG. 13, in the semiconductor storage device according to the comparative example, the hydrogen concentration in the barrier metal film 111a frequently increases and decreases from the metal film 111b side to the block dielectric film 53 side and rapidly increases at the interface with the first block film 53b. Further, in the semiconductor storage device according to the comparative example, the hydrogen concentration in the block dielectric film 53 increases from the barrier metal film 111a side to the charge storage film 61 side. On the other hand, in the semiconductor storage device 200 according to the working example, the hydrogen concentration in most areas of the barrier metal film 111a increases from the metal film 111b side to the block dielectric film 53 side. That is, the hydrogen concentration in the barrier metal film 111a increases from the metal film 111b side to the block dielectric film 53 side substantially monotonically. Further, in the semiconductor storage device 200 according to the working example, the hydrogen concentration in most areas of the block dielectric film 53 decreases from the barrier metal film 111a side to the charge storage film 61 side. That is, the hydrogen concentration in the block dielectric film 53 decreases from the barrier metal film 111a side to the charge storage film 61 side substantially monotonically. Therefore, the characteristics of changes in hydrogen concentration in the barrier metal film 111a and the block dielectric film 53 are different between the semiconductor storage device according to the comparative example and the semiconductor storage device 200 according to the working example.

In addition, the semiconductor storage device 200 according to the working example has a local maximum value LM at which the hydrogen concentration changes from an increasing trend to a decreasing trend around the interface between the barrier metal film 111a and the first block film 53b. In the example illustrated in FIG. 13, the hydrogen concentration has the local maximum value LM in the first block film 53b near the interface between the barrier metal film 111a and the first block film 53b.

Further, in the semiconductor storage device 200 according to the working example, the hydrogen concentration in a portion of the barrier metal film 111a on the block dielectric film 53 side is 1×10²⁰ atoms/cm³ or more. This portion of the barrier metal film 111a is a portion on one side of an intermediate position between one end of the barrier metal film 111a on the metal film 111b side and another end of the barrier metal film 111a on the block dielectric film 53 side, the one side being closer to the other end than to the one end.

Furthermore, in the semiconductor storage device 200 according to the working example, the amount of decrease in hydrogen concentration in the second block film 53a in a direction from the barrier metal film 111a side to the charge storage film 61 side is larger than the amount of decrease in hydrogen concentration in the first block film 53b in the direction from the barrier metal film 111a side to the charge storage film 61 side.

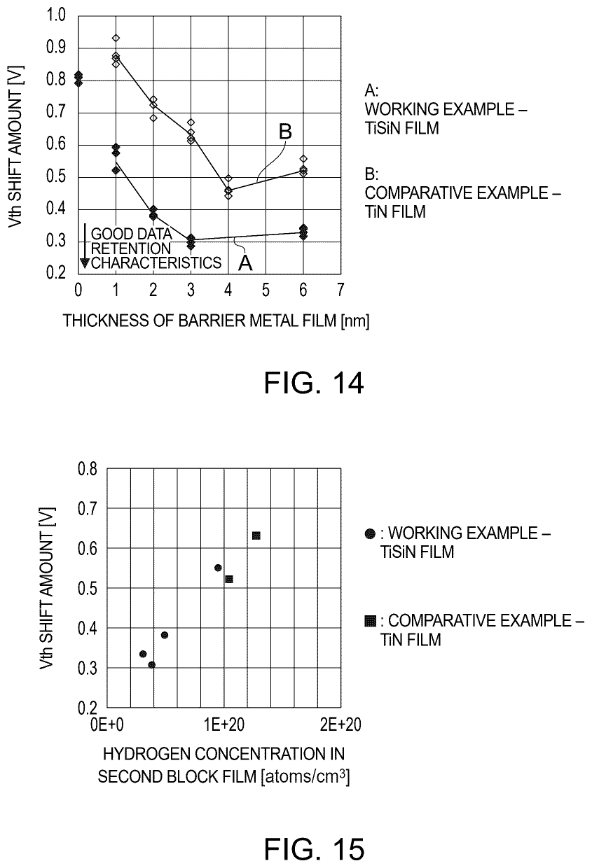

FIG. 14 is a graph illustrating a relation between the thickness of the barrier metal film 111a and the data retention characteristics in the semiconductor storage device 200 according to the working example. In FIG. 14, the horizontal axis represents the thickness (nm) of the barrier metal film 111a. The vertical axis represents a Vth shift amount (V) that is the shift amount of a threshold voltage Vth when a write process has been performed at 8 V. The smaller Vth shift amount means the better data retention characteristics. Reference sign A in FIG. 14 represents the Vth shift amount in the semiconductor storage device 200 according to the working example in which the barrier metal film 111a is formed by a TiSiN film. Reference sign B in FIG. 14 represents the Vth shift amount in the semiconductor storage device according to the comparative example in which the barrier metal film 111a is formed by a TiN film.

As is apparent from FIG. 14, at the same thickness of the barrier metal film 111a, the semiconductor storage device 200 according to the working example is smaller in Vth shift amount than the semiconductor storage device according to the comparative example. That is, at the same thickness of the barrier metal film 111a, the semiconductor storage device 200 according to the working example is superior in data retention characteristics to the semiconductor storage device according to the comparative example. Further, as is apparent from FIG. 14, in the semiconductor storage device 200 according to the working example, the Vth shift amount increases with increase in thickness of the barrier metal film 111a when the thickness of the barrier metal film 111a exceeds 3 nm. Therefore, it is preferable that the thickness of the barrier metal film 111a is 3 nm or less.

FIG. 15 is a graph illustrating a relation between the hydrogen concentration in the second block film 53a and the data retention characteristics in the semiconductor storage device 200 according to the working example. In FIG. 15, the horizontal axis represents the hydrogen concentration in the second block film 53a. The vertical axis represents the Vth shift amount (V). Four circular points in FIG. 15 represent the Vth shift amounts in the semiconductor storage device 200 according to the working example in which the barrier metal film 111a is formed by a TiSiN film. The four circular points in FIG. 15 correspond to four circular points plotted on the graph for the working example in FIG. 12. Two square points in FIG. 15 represent the Vth shift amounts in the semiconductor storage device according to the comparative example in which the barrier metal film 111a is formed by a TiN film. The two square points in FIG. 15 correspond to two square points plotted on the graph for the comparative example in FIG. 12.

As is apparent from FIG. 15, the semiconductor storage device 200 according to the working example is lower in hydrogen concentration in the second block film 53a than the semiconductor storage device according to the comparative example. Further, as is apparent from FIGS. 12 and 15, the semiconductor storage device 200 according to the working example is significantly smaller in Vth shift amount at the same thickness of the barrier metal film 111a than the semiconductor storage device according to the comparative example.

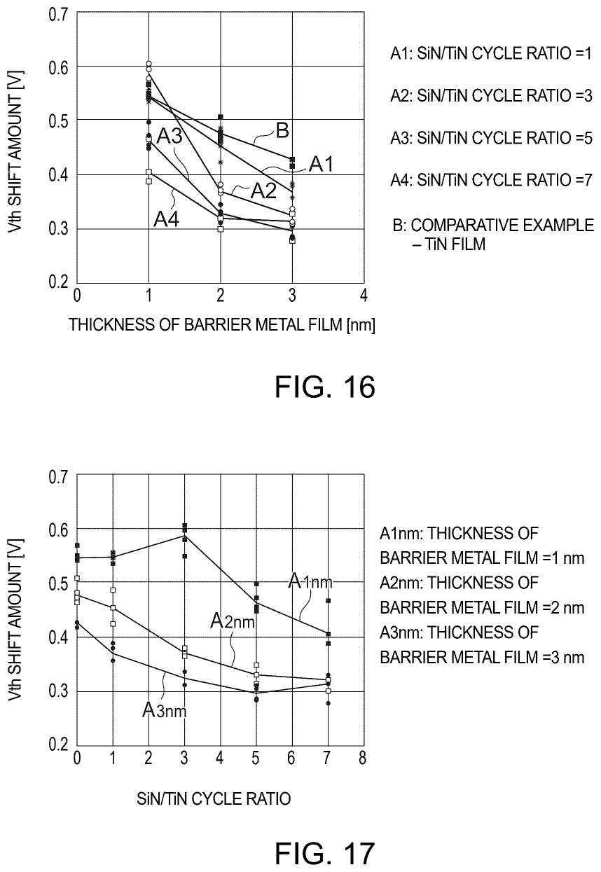

FIG. 16 is a graph illustrating a relation between the thickness of the barrier metal film 111a and the data retention characteristics in the semiconductor storage device 200 according to working examples. In FIG. 16, the horizontal axis represents the thickness (nm) of the barrier metal film 111a. The vertical axis represents the Vth shift amount (V).

Reference sign A1 in FIG. 16 represents the Vth shift amount in the semiconductor storage device 200 according to a first working example in which the barrier metal film 111a is formed by a TiSiN film. The TiSiN film (i.e., the barrier metal film 111a) of the semiconductor storage device 200 according to the first working example is formed by repeating cycle deposition of TiN and cycle deposition of SiN under a condition where the SIN/TIN cycle ratio is 1. Reference sign A2 in FIG. 16 represents the Vth shift amount in the semiconductor storage device 200 according to a second working example in which the barrier metal film 111a is formed by a TiSiN film. The TiSiN film of the semiconductor storage device 200 according to the second working example is formed by repeating cycle deposition of TiN and cycle deposition of SiN under a condition where the SIN/TIN cycle ratio is 3. Reference sign A3 in FIG. 16 represents the Vth shift amount in the semiconductor storage device 200 according to a third working example in which the barrier metal film 111a is formed by a TiSiN film. The TiSiN film of the semiconductor storage device 200 according to the third working example is formed by repeating cycle deposition of TIN and cycle deposition of SiN under a condition where the SiN/TIN cycle ratio is 5. Reference sign A4 in FIG. 16 represents the Vth shift amount in the semiconductor storage device 200 according to a fourth working example in which the barrier metal film 111a is formed by a TiSiN film. The TiSiN film of the semiconductor storage device 200 according to the fourth working example is formed by repeating cycle deposition of TiN and cycle deposition of SiN under a condition where the SiN/TIN cycle ratio is 7. Reference sign B in FIG. 16 represents the Vth shift amount in the semiconductor storage device according to the comparative example in which the barrier metal film 111a is formed by a TiN film.

As is apparent from FIG. 16, as the SiN/TIN cycle ratio is larger, the silicon content in the barrier metal film 111a is larger, so that the Vth shift amount can be reduced more effectively. In the semiconductor storage device 200 according to the third working example, the silicon concentration in the barrier metal film 111a is 54%.

FIG. 17 is a graph illustrating a relation between the SiN/TIN cycle ratio and the data retention characteristics in the semiconductor storage device 200 according to working examples. In FIG. 17, the horizontal axis represents the SiN/TIN cycle ratio. The vertical axis represents the Vth shift amount (V). Reference sign A_{1 nm} in FIG. 17 represents the Vth shift amount when the thickness of the barrier metal film 111a is 1 nm. Reference sign A_{2 nm} in FIG. 17 represents the Vth shift amount when the thickness of the barrier metal film 111a is 2 nm. Reference sign A_{3 nm} in FIG. 17 represents the Vth shift amount when the thickness of the barrier metal film 111a is 3 nm.

As is apparent from FIG. 17, when the thickness of the barrier metal film 111a is 3 nm, the Vth shift amount can be reduced more effectively.

As described above, the semiconductor storage device 200 according to the present embodiment includes the conductive layers 111, the charge storage film 61, and the block dielectric film 53. The conductive layers 111 are separated from each other in the Z direction. The conductive layers 111 each include the metal film 111b and the barrier metal film 111a covering the metal film 111b and containing titanium silicon nitride. The charge storage film 61 is opposed to side surfaces of the conductive layers 111. The block dielectric film 53 is provided between the conductive layers 111 and the charge storage film 61.

Accordingly, the barrier metal film 111a containing titanium silicon nitride can prevent diffusion of hydrogen from the metal film 111b side to the block dielectric film 53 side. Since diffusion of hydrogen can be prevented, generation of OH radicals having high oxidizing power in the block dielectric film 53 can be prevented. Since generation of OH radicals can be prevented, electron escape in which charges stored in the charge storage film 61 move toward the block dielectric film 53 can be prevented. Consequently, it is possible to prevent deterioration of the data retention characteristics.

In addition, the silicon concentration in the barrier metal film 111a is 54% or more in the present embodiment.

Accordingly, the barrier properties of the barrier metal film 111a against hydrogen can be further enhanced, so that diffusion of hydrogen from the metal film 111b side to the block dielectric film 53 side can be prevented more effectively. Consequently, it is possible to prevent deterioration of the data retention characteristics more effectively.

In the present embodiment, the thickness of the barrier metal film 111a is 3 nm or less.

Accordingly, the thickness effective for reducing the Vth shift amount can be selected, so that deterioration of the data retention characteristics can be prevented further effectively.

In the present embodiment, the block dielectric film 53 includes the first block film 53b provided to be in contact with the barrier metal film 111a and the second block film 53a provided between the first block film 53b and the charge storage film 61.

Accordingly, diffusion of hydrogen at the interface between the barrier metal film 111a and the first block film 53b can be prevented, so that the hydrogen concentration in the second block film 53a can be reduced.

In the present embodiment, the first block film 53b contains aluminum oxide, and the second block film 53a contains silicon oxide.

Accordingly, diffusion of hydrogen can be prevented effectively at the interface between the barrier metal film 111a and the first block film 53b, and the hydrogen concentration in the second block film 53a can be reduced effectively.

In the present embodiment, the hydrogen concentration at the interface between the barrier metal film 111a and the first block film 53b is higher than the hydrogen concentration in the second block film 53a.

Accordingly, diffusion of hydrogen can be prevented sufficiently at the interface between the barrier metal film 111a and the first block film 53b, so that the hydrogen concentration in the second block film 53a can be reduced more effectively.

In the present embodiment, the hydrogen concentration in the first block film 53b is higher than the hydrogen concentration in the second block film 53a.

Accordingly, the hydrogen concentration in the second block film 53a can be reduced further.

In the present embodiment, the hydrogen concentration at the interface between the barrier metal film 111a and the first block film 53b is higher than 1×10²⁰ atoms/cm³. Further, the second block film 53a includes the first portion that is lower in hydrogen concentration than the interface between the barrier metal film 111a and the first block film 53b and the second portion located on the charge storage film 61 side of the first portion. The second portion is larger in thickness than the first portion and has a hydrogen concentration of 1×10²⁰ atoms/cm³ or less which is lower than that of the first portion.

Accordingly, the hydrogen concentration can be reduced to 1×10²⁰ atoms/cm³ or less in most areas of the second block film 53a, so that deterioration of the data retention characteristics can be prevented more effectively.

In the present embodiment, the hydrogen concentration in the barrier metal film 111a increases from the metal film 111b side to the block dielectric film 53 side. The hydrogen concentration in the block dielectric film 53 decreases from the barrier metal film 111a side to the charge storage film 61 side.

Accordingly, the barrier metal film 111a and the block dielectric film 53 have characteristics of changes in hydrogen concentration which are effective for reducing the hydrogen concentration in the second block film 53a, so that deterioration of the data retention characteristics can be prevented effectively.

In the present embodiment, the hydrogen concentration in the barrier metal film 111a increases from the metal film 111b side to the block dielectric film 53 side substantially monotonically. Further, the hydrogen concentration in the block dielectric film 53 decreases from the barrier metal film 111a side to the charge storage film 61 side substantially monotonically.

Accordingly, the hydrogen concentration in the second block film 53a can be reduced more effectively.

In the present embodiment, the hydrogen concentration has a local maximum value around the interface between the barrier metal film 111a and the block dielectric film 53.

Accordingly, diffusion of hydrogen can be prevented more effectively at the interface between the barrier metal film 111a and the block dielectric film 53.

In the present embodiment, the hydrogen concentration in a portion of the barrier metal film 111a on the block dielectric film 53 side is 1×10²⁰ atoms/cm³ or more. This portion of the barrier metal film 111a is a portion on one side of an intermediate position between one end of the barrier metal film 111a on the metal film 111b side and another end of the barrier metal film 111a on the block dielectric film 53 side, the one side being closer to the other end than to the one end.

Accordingly, the barrier metal film 111a can effectively prevent diffusion of hydrogen from the metal film 111b side to the block dielectric film 53 side.

In the present embodiment, the amount of decrease in hydrogen concentration in the second block film 53a in a direction from the barrier metal film 111a to the charge storage film 61 is larger than the amount of decrease in hydrogen concentration in the first block film 53b in the direction from the barrier metal film 111a side to the charge storage film 61 side.

Accordingly, the hydrogen concentration in the second block film 53a can be reduced effectively.

According to the present embodiment, the metal film 111b contains molybdenum.

Compared to tungsten, molybdenum is superior in workability and is more advantageous to achieving finer pitch and higher integration. Meanwhile, compared to tungsten, molybdenum has a higher impurity diffusion coefficient and more easily allows hydrogen diffusion. Therefore, deterioration of the data retention characteristics caused by generation of OH radicals is larger than in a case of tungsten. However, in the present embodiment, hydrogen diffusion can be prevented effectively by the barrier metal film 111a containing TiSiN. Therefore, deterioration of the data retention characteristics can be prevented effectively.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of conductive layers separated from each other in a first direction and each comprising a metal film and a first film that covers the metal film and comprises titanium silicon nitride;
a charge storage film opposed to side surfaces of the conductive layers; and
an insulation film provided between the conductive layers and the charge storage film.

2. The device of claim 1, wherein a silicon concentration in the first film is 54% or more.

3. The device of claim 1, wherein a thickness of the first film is 3 nm or less.

4. The device of claim 1, wherein the insulation film comprises a first insulation film provided to be in contact with the first film and a second insulation film provided between the first insulation film and the charge storage film.

5. The device of claim 4, wherein the first insulation film comprises aluminum oxide, and the second insulation film comprises silicon oxide.

6. The device of claim 4, wherein an impurity concentration at an interface between the first film and the first insulation film is higher than an impurity concentration in the second insulation film.

7. The device of claim 6, wherein an impurity concentration in the first insulation film is higher than the impurity concentration in the second insulation film.

8. The device of claim 6, wherein
the impurity concentration at the interface between the first film and the first insulation film is higher than 1×10²⁰ atoms/cm³, and
the second insulation film comprises
a first portion being lower in impurity concentration than the interface, and
a second portion located on the charge storage film side of the first portion, being larger in thickness than the first portion, and having an impurity concentration of 1×10²⁰ atoms/cm³ or less which is lower than that of the first portion.

9. The device of claim 1, wherein an impurity concentration in the first film increases from the metal film side to the insulation film side, and
an impurity concentration in the insulation film decreases from the first film side to the charge storage film side.

10. The device of claim 9, wherein the impurity concentration in the first film increases from the metal film side to the insulation film side substantially monotonically, and the impurity concentration in the insulation film decreases from the first film side to the charge storage film side substantially monotonically.

11. The device of claim 9, wherein the impurity concentration has a local maximum value around an interface between the first film and the first insulation film.

12. The device of claim 9, wherein an impurity concentration of a portion of the first film on the insulation film side is 1×10²⁰ atoms/cm³ or more.

13. The device of claim 12, wherein the portion of the first film is a portion on a side of an intermediate position between one end of the first film on the metal film side and another end of the first film on the insulation film side, the side being closer to the other end than to the one end.

14. The device of claim 12, wherein
the insulation film comprises a first insulation film provided to be in contact with the first film and a second insulation film provided between the first insulation film and the charge storage film, and
the second insulation film is lower in impurity concentration than an interface between the first film and the first insulation film and partially has an impurity concentration of 1×10²⁰ atoms/cm³ or less.

15. The device of claim 14, wherein an amount of decrease in impurity concentration in the second insulation film in a direction from the metal film side to the charge storage film side is larger than an amount of decrease in impurity concentration in the first insulation film in the direction from the metal film side to the charge storage film side.

16. The device of claim 6, wherein the impurity is hydrogen.

17. The device of claim 1, wherein the metal film comprises molybdenum.

18. The device of claim 1, further comprising:
a plurality of insulation layers separated from each other in the first direction, the insulation layers and the conductive layers being alternately stacked;
a third insulation film provided on a side surface of the charge storage film on an opposite side to the insulation film;
a semiconductor film provided on a side surface of the third insulation film on an opposite side to the charge storge film; and
a fourth insulation film provided on a side surface of the semiconductor film on an opposite side to the third insulation film.

19. A manufacturing method of a semiconductor device, comprising:
forming a plurality of conductive layers separated from each other in a first direction, the conductive layers each comprising a metal film and a first film that covers the metal film and comprises titanium silicon nitride;
forming a charge storage film opposed to side surfaces of the conductive layers; and
forming an insulation film between the conductive layers and the charge storage film.

20. The method of claim 19, further comprising:
forming a stacked film comprising a plurality of insulation layers and a plurality of first layers alternately stacked in the first direction;
forming a first concave portion penetrating through the stacked film; and
forming a plurality of second concave portions in the stacked film by removing the first layers, wherein
the forming the insulation film includes forming a second insulation film in the first concave portion and forming a first insulation film in the second concave portions,
the charge storage film is formed in the first concave portion via the second insulation film, and
the forming the conductive layers includes forming the first film in the second concave portions and forming the metal film in the second concave portions via the first film.
